(19) United States
(12) Patent Application Publication
(10) Pub. No.: US 2026/0254199 A1
(43) Pub. Date: Aug. 27, 2026

(54) LASER ELEMENT AND ELECTRONIC DEVICE

(71) Applicant: SONY GROUP CORPORATION, TOKYO (JP)

(72) Inventors: MASANAO KAMATA, TOKYO (JP); GEN YONEZAWA, TOKYO (JP)

(21) Appl. No.: 19/161,331

(22) PCT Filed: Mar. 15, 2024
(86) PCT No.: PCT/JP2024/010158

§ 371 Date: Sep. 2, 2025

(30) Foreign Application Priority Data
Mar. 24, 2023 (JP) 2023-048504

(51) Int. Cl. H01S 5/10; H01S 3/0941; H01S 3/1115; H01S 3/16; H01S 5/183

(52) U.S. Cl. CPC H01S 5/1021; H01S 3/09415; H01S 3/1115; H01S 3/1618; H01S 3/1643; H01S 5/18305; H01S 5/18361

(57) ABSTRACT

The present disclosure can generate laser light having an ultrashort pulse and high peak power, be miniaturized, and improve light-pulse light conversion efficiency. A laser element includes: a laminated semiconductor layer that includes a first reflection layer for a first wavelength and an active layer that performs surface light emission at the first wavelength; a laser medium that is disposed on a rear side of an optical axis of the laminated semiconductor layer, and includes a second reflection layer for a second wavelength on a first surface facing the laminated semiconductor layer and a third reflection layer for the first wavelength on a second surface on an opposite side to the first surface; a fourth reflection layer for the second wavelength that is disposed further toward the rear side of the optical axis than the second surface; a first resonator that resonates light of the first wavelength between the first reflection layer and the third reflection layer; a second resonator that resonates light of the second wavelength between the second reflection layer and the fourth reflection layer; and a semiconductor saturable absorber that is disposed between the third reflection layer and the fourth reflection layer and generates the light of the second wavelength by mode-locking, and the optical axis of the laminated semiconductor layer and an optical axis of the laser medium are uniaxially arranged.

### TECHNICAL FIELD

The present disclosure relates to a laser element and an electronic device.

### BACKGROUND ART

A laser technique is used in various fields such as microfabrication, medical, or ranging fields. A mode-locked laser can generate laser light having a considerably short pulse width and very high peak power, compared to conventional Q switch lasers, and can propagate total energy of the laser light before heat is generated, and consequently is expected to be applied for use in non-thermal laser machining and sensing (see NPL 1).

### CITATION LIST

### Non Patent Literature

[NPL 1] Femtosecond pulses from a modelocked integrated external-cavity surface emitting laser (MIXSEL) https://opg.optica.org/oe/fulltext.cfm?uri=oe-21-21-24904&id=268839

### SUMMARY

### Technical Problem

However, a laser device according to NPL 1 needs to allow excitation light to enter therein from an outside, has a complicated structure, and is difficult to be miniaturized. More specifically, the laser device according to NPL 1 allows the excitation light to enter from a diagonal direction of the optical axis. Hence, a gain medium to be provided inside the laser device needs to be made extremely thin because of mode match between the excitation light and oscillation light. Moreover, the gain medium needs to absorb the excitation light in two paths at maximum, and needs to have a high absorption coefficient. Hence, the gain medium having a semiconductor quantum well structure is used in NPL 1.

However, since the gain medium of the semiconductor quantum well structure has a short carrier life and cannot sufficiently accumulate energy, light-pulse light conversion efficiency at a time of generation of laser light having an ultrashort pulse is less than 1%. Although it is possible to extend the carrier life and improve the light-pulse light conversion efficiency by using a solid-state laser medium, the absorption coefficient is not as large as those of semiconductor materials and therefore it is necessary to increase the thickness, and, as a result, it is not possible to secure mode match between the excitation light and the oscillation light.

To solve the above problem, the present disclosure provides a laser element and an electronic device that can generate laser light having an ultrashort pulse and high peak power, be miniaturized, and improve light-pulse light conversion efficiency.

### Solution to Problem

To solve the above problem, the present disclosure provides a laser element that includes:
a laminated semiconductor layer that includes a first reflection layer for a first wavelength and an active layer that performs surface light emission at the first wavelength;
a laser medium that is disposed on a rear side of an optical axis of the laminated semiconductor layer, and includes a second reflection layer for a second wavelength on a first surface facing the laminated semiconductor layer and a third reflection layer for the first wavelength on a second surface on an opposite side to the first surface;
a fourth reflection layer for the second wavelength that is disposed further toward the rear side of the optical axis than the second surface;
a first resonator that resonates light of the first wavelength between the first reflection layer and the third reflection layer;
a second resonator that resonates light of the second wavelength between the second reflection layer and the fourth reflection layer; and
a semiconductor saturable absorber that is disposed between the third reflection layer and the fourth reflection layer and generates the light of the second wavelength by mode-locking, and
the optical axis of the laminated semiconductor layer and an optical axis of the laser medium are uniaxially arranged.

The laminated semiconductor layer, the laser medium, and the semiconductor saturable absorber may be an integrated structure in which optical axes of the laminated semiconductor layer, the laser medium, and the semiconductor saturable absorber are uniaxially arranged.

The semiconductor saturable absorber may include a quantum well structure that has a predetermined modulation depth and a recovery time.

The semiconductor saturable absorber may be of a transmission type and have a modulation depth ΔR of 0.5 to 2%, and a recovery time τ_{fast} of less than 500 fs (femtoseconds).

The laser medium may be a solid-state laser medium.

The laser medium may be an ion-doped type solid-state laser medium.

The second resonator may include a chirp mirror.

At least one of the second reflection layer and the fourth reflection layer may be the chirp mirror.

When a group delay dispersion GDD_{cavity} of the chirp mirror, a group delay dispersion GDD_{gain medium} of the laser medium, and a group delay dispersion GDD_{SA} of the semiconductor saturable absorber satisfy a relationship of following expression (1)

$${GDD}_{cavity} = 2 {GDD}_{gain medium} + 2 {GDD}_{DBR} + {GDD}_{SA} , \qquad ( 1 )$$

the group delay dispersion GDD_{cavity} of the chirp mirror may be set to satisfy following expression (2)

$$- 2000 {fs}^{2} < {GDD}_{cavity} < 2000 {fs}^{2} . \qquad ( 2 )$$

The second reflection layer may be a shortwave wavelength transmission filter.

The second reflection layer may include
a first region disposed on the rear side of the optical axis, and
a second region laminated on the first region and disposed on a front side of the optical axis,
the first region may be formed of a material having higher light durability than light durability of the second region, and
the second region may be formed of a material having higher light blocking performance than light blocking performance of the first region.

The first region may be formed by alternately laminating a first material layer and a second material layer having different refractive indices from each other, and the second region may be formed by alternately laminating a third material layer and a fourth material layer having different refractive indices from each other.

A difference between the refractive indices of the third material layer and the fourth material layer may be greater than a difference between the refractive indices of the first material layer and the second material layer.

A difference between band gaps of the third material layer and the fourth material layer may be greater than a difference between band gaps of the first material layer and the second material layer.

A difference between laser-induced damage thresholds of the third material layer and the fourth material layer may be greater than a difference between laser-induced damage thresholds of the first material layer and the second material layer.

A degree of a difference among thermal expansion coefficients of the laminated semiconductor layer, the laser medium, and the semiconductor saturable absorber may be 20% or less.

Furthermore, the present disclosure provides an electronic device that includes: a laser element; and
an imaging unit that generates image data, based on irradiation light of the laser element or reflection light of the irradiation light,
the laser element includes:
a laminated semiconductor layer that includes a first reflection layer for a first wavelength and an active layer that performs surface light emission at the first wavelength;
a laser medium that is disposed on a rear side of an optical axis of the laminated semiconductor layer, and includes a second reflection layer for a second wavelength on a first surface facing the laminated semiconductor layer and a third reflection layer for the first wavelength on a second surface on an opposite side to the first surface;
a fourth reflection layer for the second wavelength that is disposed further toward the rear side of the optical axis than the second surface;
a first resonator that resonates light of the first wavelength between the first reflection layer and the third reflection layer;
a second resonator that resonates light of the second wavelength between the second reflection layer and the fourth reflection layer; and
a semiconductor saturable absorber that is disposed between the third reflection layer and the fourth reflection layer and generates the light of the second wavelength by mode-locking, and
the optical axis of the laminated semiconductor layer and an optical axis of the laser medium are uniaxially disposed.

### BRIEF DESCRIPTION OF DRAWINGS

FIG. 1 is a cross-sectional view illustrating a schematic configuration of a laser element according to a first embodiment.

FIG. 2 is a cross-sectional view illustrating an electrode structure of an excitation light source according to the first embodiment.

FIG. 3 is a plan view illustrating arrangement of electrodes of the laser element according to the first embodiment.

FIG. 4 is a perspective view illustrating a configuration of a laser device according to one comparative example.

FIG. 5 is a cross-sectional view of a laser element and an output coupler according to the one comparative example.

FIG. 6 is a cross-sectional view illustrating a schematic configuration of the laser element according to one modification of the first embodiment.

FIG. 7 is a graph showing the characteristics of a second reflection layer according to a second embodiment.

FIG. 8 is a graph showing the characteristics of materials that can be used for the second reflection layer.

FIG. 9 is a view illustrating an example of a schematic configuration of an endoscopic system.

FIG. 10 is a block diagram illustrating an example of a functional configuration of a camera and a CCU illustrated in FIG. 9.

FIG. 11 is a diagram illustrating an example of a schematic configuration of a microsurgery system.

### DESCRIPTION OF EMBODIMENTS

Hereinafter, embodiments of a laser element and an electronic device will be described with reference to the drawings. Although main components of the laser element and the electronic device will be mainly described below, the laser element and the electronic device may include components and functions that are not illustrated or explained. The following description does not exclude components or functions that are not illustrated or described.

### First Embodiment

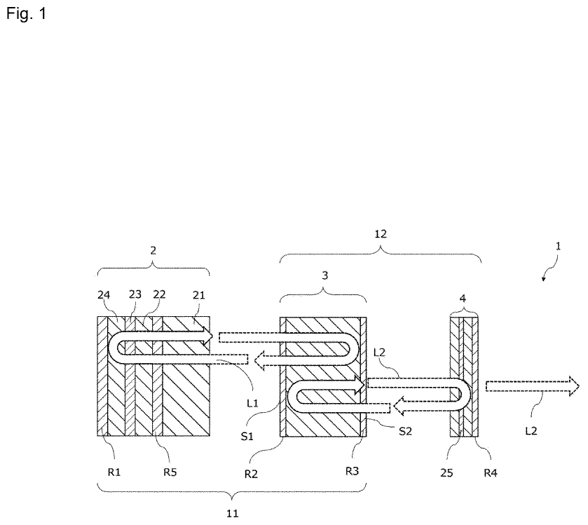

FIG. 1 is a cross-sectional view illustrating a schematic configuration of a laser element 1 according to a first embodiment. The laser element 1 includes an excitation light source (laminated semiconductor layer) 2, a laser medium 3, and a saturable absorber (semiconductor saturable absorber) 4. The laser element 1 has a structure formed by integrating the excitation light source 2, the laser medium 3, and the saturable absorber 4. The optical axes of the excitation light source 2, the laser medium 3, and the saturable absorber 4 are uniaxially arranged.

The excitation light source 2 generates excitation light L1 for exciting the laser medium 3. The excitation light source 2 is formed of a semiconductor layer (hereinafter, a laminated semiconductor layer) having a laminated structure in which a substrate 21, a fifth reflection layer R5, a cladding layer 22, an active layer 23, a cladding layer 24, and a first reflection layer R1 are laminated in this order.

Although FIG. 1 illustrates the excitation light source 2 having a bottom emission type configuration that emits the excitation light (light of a first wavelength) L1 of a Continuous Wave (CW) from the substrate 21 side, the excitation light source 2 may also employ a top emission type configuration that emits CW excitation light from the first reflection layer R1 side. Furthermore, light of the first wavelength does not necessarily need to be a continuous wave, and may be a pulse wave.

The substrate 21 is, for example, an n-GaAs substrate. The n-GaAs substrate absorbs a certain rate of the excitation light L1 that is the excitation wavelength of the excitation light source 2, and is therefore desirably made as thin as possible to suppress absorption of the excitation light L1. On the other hand, the substrate 21 desirably has such a thickness that the mechanical strength at a time when the substrate 21 is bonded to, for example, other members can be maintained.

The active layer 23 performs surface light emission of the excitation light L1. The cladding layers 22 and 24 to be disposed on both sides of the active layer 23 are, for example, AlGaAs cladding layers. The first reflection layer R1 needs to reflect the excitation light L1 without allowing the excitation light L1 to transmit therethrough. The fifth reflection layer R5 has a certain transmittance for the excitation light L1. For example, Distributed Bragg Reflectors (DBRs) that enable electrical conduction are used for the first reflection layer R1 and the fifth reflection layer R5. In FIG. 1, a current is injected externally from an unillustrated electrode through the first reflection layer R1 and the fifth reflection layer R5 to cause recombination and light emission in the quantum well in the active layer 23 to generate the excitation light L1.

The fifth reflection layer R5 is disposed on, for example, the substrate 21. For example, the fifth reflection layer R5 includes a multilayer reflection film made of Al_{z1}Ga_{1-z1}As/Al_{z2}Ga_{1-z2}As (0≤z1≤z2≤1) doped with an n-type dopant (e.g., silicon). The fifth reflection layer R5 is also referred to as an n-DBR.

The active layer 23 includes a multiple quantum well layer formed by laminating, for example, an Alₓ₁In_{y1}Ga_{1-x1-y1}As layer and an Alₓ₃In_{y3}Ga_{1-x3-y3}As layer.

The first reflection layer R1 includes a multi-reflection film made of, for example, Al_{z3}Ga_{1-z3}As/Al_{z4}Ga_{1-z4}As (0≤z3≤z4≤1) doped with a p-type dopant (e.g., carbon). The first reflection layer R1 is also referred to as a p-DBR.

Respective semiconductor layers (the fifth reflection layer R5, the cladding layer 22, the active layer 23, the cladding layer 24, and the first reflection layer R1) in the excitation light source 2 that functions as an excitation light resonator can be formed using a crystal growth method such as a Metal Organic Chemical Vapor Deposition (MOCVD) method or a Molecular Beam Epitaxy (MBE) method. Furthermore, each of the semiconductor layers can be driven by current injection after a process such as mesa etching for element isolation, formation of an insulating film, deposition of an electrode film, and the like after crystal growth.

The excitation light source 2 may be a member that can emit excite the laser medium 3 and generate the excitation light, and a specific material does not matter. For example, a material used for the excitation light source 2 may be a crystalline material or may be an amorphous material such as ceramics. The excitation light source 2 only needs to enable the excitation light L1 to enter the laser medium 3, and it is not necessarily necessary to provide a light control member such as a condensing member.

In FIG. 1, a detailed layer configuration such as an electrode structure of the excitation light source 2 is omitted. A detailed configuration of the excitation light source 2 will be described later.

The laser medium 3 is disposed on a side opposite to the fifth reflection layer R5 of the substrate 21 of the excitation light source 2, that is, on a rear side of an optical axis. The laser medium 3 includes a second reflection layer R2 and a third reflection layer R3. Note that, in this description, an emission direction of laser light emitted along the optical axis of the laser element 1 will be referred to as a rear side of the optical axis, and a direction opposite to the emission direction will be referred to as a front side of the optical axis.

The second reflection layer R2 is disposed on a first surface S1 facing the light emission surface of the excitation light source 2. The third reflection layer R3 is disposed on a second surface S2 closer to a rear side of the optical axis than the first surface S1. The laser medium 3 is disposed between the second reflection layer R2 and the third reflection layer R3.

The laser medium 3 is excited by the excitation light L1 and emits oscillation light (light of a second wavelength) L2. The laser medium 3 is disposed between the excitation light source 2 and the saturable absorber 4.

For the laser medium 3, for example, an ion-doped type solid-state laser medium is used. For a material of the laser medium 3, for example, Yttrium Aluminum Garnet (YAG) crystal Yb:YAG doped with Ytterbium (Yb) is used. Note that, although the laser medium 3 is desirably a solid-state laser medium, a semiconductor laser medium can be also used.

The solid-state laser medium has a lower absorption coefficient of the excitation light L1 compared to a semiconductor laser medium, and has a longer carrier life and is easy to accumulate energy of the excitation light L1. Accordingly, when there is no restriction on the absorption coefficient of the excitation light L1, the laser medium 3 is desirably a solid-state laser medium. By using the solid-state laser medium, it is possible to improve light-pulse light conversion efficiency.

For the laser medium 3, not only Yb:YAG, but also, for example, a material of one of Nd:YAG, Nd:YVO4, Nd:YLF, Nd:glass, Yb:YAG, Yb:YLF, Yb:FAP, Yb:SFAP, Yb:YVO, Yb:glass, Yb:KYW, Yb:BCBF, Yb:YCOB, Yb:GdCOB, and Yb:YAB may be used.

Furthermore, the laser medium 3 may be the four-level system solid-state laser medium, or may be a three-level system solid-state laser medium. In this regard, since each crystal has a different appropriate excitation wavelength, a semiconductor material in the excitation light source 2 needs to be selected according to the material of the laser medium 3. For example, the laser medium 3 made of Ti:S (titanium/sapphire) is used for the excitation light source 2 made of GaN (gallium nitride)

Of a pair of the second reflection layer R2 and the third reflection layer R3, the second reflection layer R2 provided on the excitation light source 2 side needs to allow, for example, the excitation light L1 emitted from the excitation light source 2 to transmit therethrough, and reflect the oscillation light L2 emitted from the laser medium 3 at a predetermined reflectance.

On the other hand, the third reflection layer R3 provided on the opposite side to the excitation light source 2 reflects, for example, the excitation light L1 emitted from the excitation light source 2 at the predetermined reflectance, and allows the oscillation light L2 emitted from the laser medium 3 to transmit therethrough.

For example, a dielectric multilayer film is used for the second reflection layer R2 and the third reflection layer R3. The thickness of the dielectric multilayer film is, for example, a quarter of a laser oscillation wavelength, a total number is several layers to several hundred layers, and SiO₂ or SiN may be used for the material.

The excitation light source 2 and the laser medium 3 constitute a first resonator 11. Inside the first resonator 11, three reflection layers (the first reflection layer R1, a fifth reflection layer R5, and the third reflection layer R3) are provided. Hence, the first resonator 11 has a coupled cavity structure.

The laser element 1 in FIG. 1 includes the saturable absorber 4 disposed facing the third reflection layer R3 of the laser medium 3. The saturable absorber 4 includes the fourth reflection layer R4.

The saturable absorber 4 is a member that has the property that a light absorption rate becomes small due to saturation of light absorption. For example, the saturable absorber 4 absorbs the oscillation light L2 emitted from the laser medium 3, and the transmittance of the saturable absorber 4 increases as the oscillation light L2 is absorbed. The saturable absorber 4 becomes transparent when the electron density of an excitation level increases and the excitation level is satisfied. Thus, a Q value of the optical resonator (second resonator 12) disposed between the second reflection layer R2 and the fourth reflection layer R4, and laser oscillation occurs.

Furthermore, in the saturable absorber 4, mode-locking occurs that makes the intensity of light extremely high in a short period during which the peaks of light of a plurality of wavelengths propagating inside the second resonator 12 are aligned. As a result of the mode-locking, the saturable absorber 4 emits the oscillation light L2 having an ultrashort pulse width at the order of femtoseconds. To generate the oscillation light L2 having the ultrashort pulse width, a transmission type Semiconductor Saturable Absorber Mirrors (SESAM and hereinafter referred to as a semiconductor saturable absorber) is used. The semiconductor saturable absorber 4 has, for example, a semiconductor quantum well structure (quantum well 25) in which an absorption layer (InGaAs) of a quantum well is formed on a DBR of GaAs/AlAs. The semiconductor saturable absorber 4 has a predetermined modulation depth and a recovery time to mode-lock the oscillation light L2. More specifically, the semiconductor saturable absorber 4 desirably has a recovery time τfast typical value of 500 fs or less and a modulation depth ΔR typical value of 0.5 to 2%.

The fourth reflection layer R4 is a partial reflection layer having a function of an output coupler. The fourth reflection layer R4 is disposed closer to the a rear side of the optical axis than the second surface S2. More specifically, the fourth reflection layer R4 is disposed on an end surface of the saturable absorber 4 on the opposite side to the laser medium 3 or on the rear side of the laser medium 3.

The second resonator 12 disposed between the second reflection layer R2 and the fourth reflection layer R4 resonates the oscillation light L2 between the second reflection layer R2 and the fourth reflection layer R4. The second resonator 12 includes a chirp mirror. More specifically, at least one of the second reflection layer R2 and the fourth reflection layer R4 is a chirp mirror. The chirp mirror performs dispersion control on the wavelength of the oscillation light L2 by alternately disposing high refractive index layers and low refractive index layers, and gradually changing the thicknesses of these layers. Wavelength dispersion of the oscillation light L2 is compensated by providing the chirp mirror.

The above-described chirp mirror needs to focus on Group Delay Dispersion (GDD). A group delay dispersion GDD_{cavity} of the oscillation light L2 of the chirp mirror is expressed by following expression (1) using a group delay dispersion GDD_{gain medium} of the laser medium 3, a group delay dispersion GDD_{SA} of the saturable absorber 4, and a Group Delay Dispersion GDD_{DBR} of each reflection layer.

$${GDD}_{cavity} = 2 {GDD}_{gain medium} + 2 {GDD}_{DBR} + {GDD}_{SA} \qquad ( 1 )$$

Here, the group delay dispersion GDD_{cavity} of the oscillation light L2 of the chirp mirror desirably falls within the range of following expression (2).

$$- 2000 {fs}^{2} < {GDD}_{cavity} < 2000 {fs}^{2} \qquad ( 2 )$$

The laser element 1 according to the present embodiment has an integrated structure including the first resonator 11 and the second resonator 12. Furthermore, the first resonator 11 and the second resonator 12 share the laser medium 3. The laser element 1 generates the excitation light L1 in the first resonator 11, accumulates energy of the excitation light L1 in the laser medium 3, thereby excites the laser medium 3, and generates the oscillation light L2 in the second resonator 12. Hereinafter, the operation of the laser element 1 will be described.

By injecting a current into the active layer 23 through an unillustrated electrode of the excitation light source 2, the active layer 23 performs surface light emission on the excitation light L1. The first resonator 11 resonates the excitation light L1 between the first reflection layer R1 of the excitation light source 2 and the third reflection layer R3 of the laser medium 3. Thus, the power of the excitation light L1 is trapped in the first resonator 11, and the laser medium 3 is excited.

Here, the excitation light L1 reciprocates between the first reflection layer R1 and the third reflection layer R3 over and over. Consequently, the laser medium 3 can absorb the excitation light L1 even when the absorption coefficient is small. Consequently, a solid-state laser medium having higher light-pulse light conversion efficiency can be used for the laser medium 3 of the laser element 1. A structure that the excitation light L1 reciprocates in the laser medium 3 over and over is also called a multi-path structure.

The laser medium 3 is excited by the excitation light L1 and generates the oscillation light L2 of the second wavelength. At a beginning stage at which laser oscillation occurs in the second resonator 12, the oscillation light L2 is absorbed by the saturable absorber 4, and the fourth reflection layer R4 on an emission surface side of the saturable absorber 4 does not emit the oscillation light L2.

Thereafter, when the excitation light L1 is absorbed by the laser medium 3 and enters a sufficiently excited state, the power of the oscillation light L2 increases. When the power of the oscillation light L2 exceeds a predetermined threshold, the light absorption rate in the saturable absorber 4 rapidly decreases, and the oscillation light L2 generated in the laser medium 3 can transmit through the saturable absorber 4. Thus, the second resonator 12 resonates the oscillation light L2 between the second reflection layer R2 of the laser medium 3 and the fourth reflection layer R4 of the saturable absorber 4. Light of a plurality of wavelengths including the wavelength of the oscillation light L2 performs a resonance operation between the second reflection layer R2 and the fourth reflection layer R4, mode-locking occurs at a short timing when peaks of the light of these wavelengths match, and the oscillation light L2 having an ultrashort pulse width and high power is generated.

For the sake of thermal durability of the laser element 1, the degree of a difference between thermal expansion coefficients of the excitation light source 2, the laser medium 3, and the saturable absorber 4 is desirably 20% or less.

The laser element 1 may include additional members such as a polarization control element, a condensing element, and a spacer in addition to the layer configuration in FIG. 1.

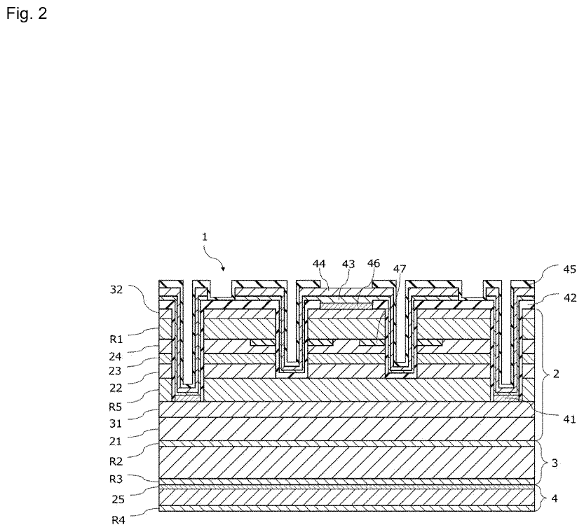

FIG. 2 is a cross-sectional view illustrating an electrode structure of the excitation light source 2 according to the first embodiment. In addition to the layer configuration in FIG. 1, the excitation light source 2 includes contact layers 31 and 32, n electrodes 41, an insulation layer 42, a PAD 43, a plating layer 44, an insulation layer 45, a p electrode 46, and an oxide layer 47. The contact layer 31 is bonded to the fifth reflection layer R5, and the contact layer 32 is bonded to the first reflection layer R1.

The n electrodes 41 are conducted with the contact layer 31. The contact layer 31 is bonded to the fifth reflection layer R5, and the fifth reflection layer R5 is bonded to the cladding layer 22. Furthermore, the p electrode 46 is bonded to the PAD 43, the PAD 43 is bonded to the contact layer 32, the contact layer 32 is bonded to the first reflection layer R1, and the first reflection layer R1 is bonded to the cladding layer 24. Thus, a current corresponding to a voltage difference between the p electrode 46 and the n electrode 41 flows in the active layer 23, and the excitation light L1 is generated.

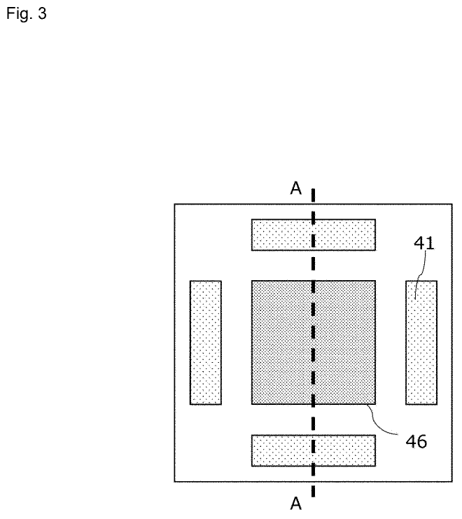

FIG. 3 is a plan view illustrating arrangement of electrodes of the laser element 1 according to the first embodiment. FIG. 2 is a cross-sectional view taken along a direction of a line A-A in FIG. 3. As illustrated in FIG. 3, a plurality of the n electrodes 41 are disposed around the p electrode 46. Note that illustration of other than the n electrodes 41 and the p electrode 46 is omitted in FIG. 3.

The arrangement of the electrodes 41 and 46 in FIGS. 2 and 3 is an example, and various modifications thereof are conceivable.

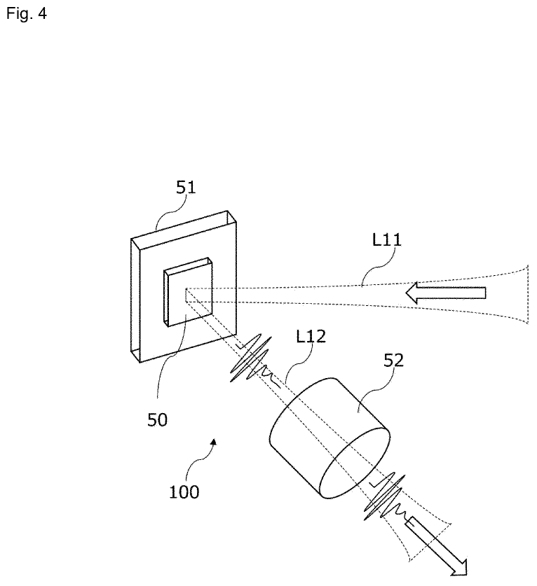

FIG. 4 is a perspective view illustrating a configuration of a laser device 100 according to one comparative example. The laser device 100 includes a laser element 50, a heat sink 51, and an output coupler 52.

The laser element 50 is a photoexcitation Modelocked Integrated External-Cavity Surface Emitting Laser (MIXSEL) chip. Excitation light L11 enters the laser element 50 from an external light source. The laser element 50 generates oscillation light L12 that is mode-locked laser between the laser element 50 and the output coupler 52.

The heat sink 51 is, for example, a diamond heat sink, and absorbs heat generated by the laser element 50.

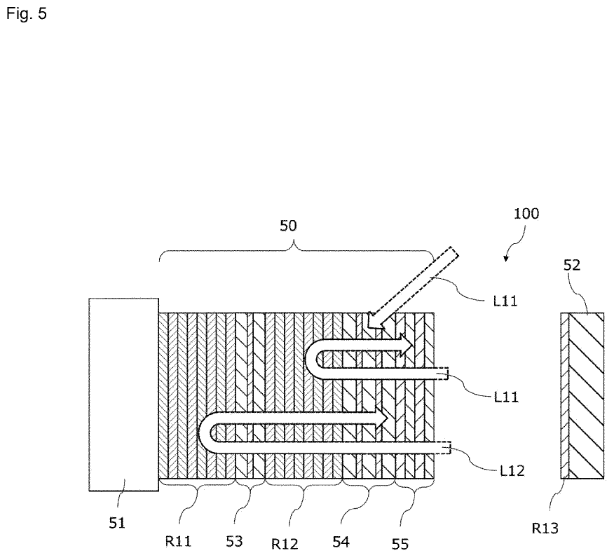

FIG. 5 is a cross-sectional view of the laser element 50 and the output coupler 52 according to the one comparative example illustrated in FIG. 4. The laser element 50 has a semiconductor laminated structure in which an oscillation light mirror R11, a saturable absorber 53, an excitation light mirror R12, a gain medium 54, and an Anti-Reflection (AR) member 55 are laminated in order from the heat sink 51 side. Furthermore, the output coupler 52 also includes an oscillation light mirror R13.

The excitation light mirror R12 reflects at a predetermined reflectance the excitation light L11 entering from the outside. The gain medium 54 is excited by the excitation light L11 and generates the oscillation light L12 similarly to the laser medium 3 in FIG. 1.

For the saturable absorber 53 of the laser device 100, a transmission type SESAM semiconductor saturable absorber that mode-locks the oscillation light L12 is used similarly to the saturable absorber 4 in FIG. 1. The AR member 55 suppresses reflection loss of the oscillation light L12.

The reflection light mirror R11 of the laser element 50 and the reflection light mirror R13 of the output coupler 52 reflect the oscillation light L12 at a predetermined reflectance. The laser device 100 resonates the oscillation light L12 between the reflection light mirror R11 and the reflection light mirror R13 to generate the mode-locked reflection light L12.

The laser device 100 has a disk laser type structure that includes an unillustrated external light source that emits the excitation light L11. The excitation light L11 diagonally enters the optical axes of the saturable absorber 53, the gain medium 54, and the like. The optical axis of the excitation light L11 and the optical axis of the oscillation light L12 are misaligned, and therefore it is not easy to mode-match the excitation light L11 and the oscillation light L12, it is difficult to miniaturize the laser device 100, and it is necessary to make the gain medium 54 very thin.

The laser device 100 does not have a structure in which the excitation light L11 passes through the gain medium 54 many times. The excitation light L11 enters the gain medium 54 from the outside, and the excitation light L11 having transmitted through the gain medium 54 and being reflected by the excitation light mirror R12 enters the gain medium 54 again. As described above, the excitation light L11 entering the gain medium 54 includes only two paths at the maximum.

Therefore, the laser device 100 needs to cause the very thin gain medium 54 to absorb total energy of the excitation light L11 in two paths at maximum. Therefore, a semiconductor gain medium needs to be used for the gain medium 54. The semiconductor gain medium has a short carrier life and cannot accumulate sufficient energy, and therefore has very low light-pulse light conversion efficiency at a time of generation of an ultrashort pulse.

As described above, the laser device 100 has various problems. By contrast with this, in the laser element 1 according to the present embodiment, the respective optical axes of the excitation light source 2, the laser medium 3, and the saturable absorber 4 are uniaxially arranged, the first resonator 11 that resonates the excitation light L1 and the second resonator L2 that resonates the oscillation light L2 are overlapped in the laser medium 3. Consequently, it is possible to easily achieve structure integration, eliminate restriction of the absorption coefficient of the laser medium 3, and apply a solid-state laser medium having higher light-pulse light conversion efficiency. Furthermore, the excitation light L1 can be generated inside the laser element 1, so that it is not necessary to allow the excitation light to enter from the outside, and it is possible to easily mode-match the excitation light L1 and the oscillation light L2, and achieve a single chip structure by a semiconductor process.

### Modification of First Embodiment

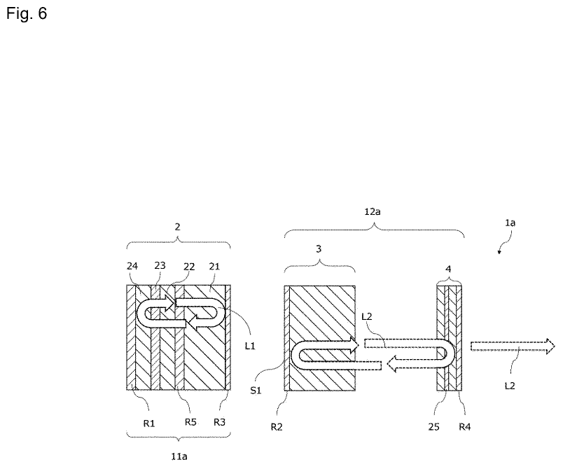

FIG. 6 is a cross-sectional view illustrating a schematic configuration of a laser element 1a according to one modification of the first embodiment. The laser element 1a differs from the laser element 1 in that the third reflection layer R3 is disposed in the excitation light source 2. The third reflection layer R3 is disposed on a surface of the excitation light source 2 facing the laser medium 3.

A first resonator 11a resonates the excitation light L1 between the first reflection layer R1 and the third reflection layer R3. A second resonator 12a resonates the oscillation light L2 between the second reflection layer R2 and the fourth reflection layer R4. In the laser element 1a in FIG. 6, the first resonator 11a and the second resonator 12a do not overlap. Accordingly, the laser medium 3 cannot accumulate energy of the excitation light L1 and cannot be excited by the excitation light L1. In this regard, the saturable absorber 4 is formed of a semiconductor saturable absorber similarly to FIG. 1, and can generate the oscillation light L2 having an ultrashort pulse width by mode-locking.

While the structure of the laser medium 3 of the laser element 1a in FIG. 6 can be simplified compared to the laser element 1 in FIG. 1, peak power of the oscillation light L2 emitted from the saturable absorber 4 is lower than that of the laser element 1 in FIG. 1.

As described above, the laser element 1 according to the first embodiment resonates the excitation light L1 in the first resonator 11 including the excitation light source 2 and the laser medium 3, accumulates the energy of the excitation light L1 in the laser medium 3, excites the laser medium 3, and resonates the oscillation light L2 in the second resonator 12 including the laser medium 3 and the saturable absorber 4. By using a semiconductor saturable absorber as the saturable absorber 4, it is possible to mode-lock the oscillation light L2, and generate the oscillation light L2 having an ultrashort pulse width and high peak power. The respective optical axes of the excitation light source 2, the laser medium 3, and the saturable absorber 4 of the laser element 1 are uniaxially arranged and can be formed by the semiconductor process, so that it is possible to easily achieve single chip formation. Furthermore, the laser element 1 according to the present embodiment does not need to allow excitation light to enter from the outside, can easily mode-match the excitation light L1 and the oscillation light L2, and has no restriction on the absorption coefficient of the laser medium 3 thanks to the multi-path structure, so that it is possible to use the solid-state laser medium as the laser medium 3, and improve light-pulse light conversion efficiency.

### Second Embodiment

Since the oscillation light L2 emitted from the laser element according to the first embodiment has a strong peak output, the second reflection layer R2 is concerned to cause optical damage, and special consideration is necessary for a material of the second reflection layer R2. Furthermore, the second reflection layer R2 needs to function as a shortwave wavelength transmission filter, and is requested to allow the excitation light L1 of a short wavelength to transmit therethrough and block the oscillation light L2 of a long wavelength. As described above, the second reflection layer R2 is requested to have two of light durability for preventing optical damage and the light blocking property for blocking the oscillation light L2.

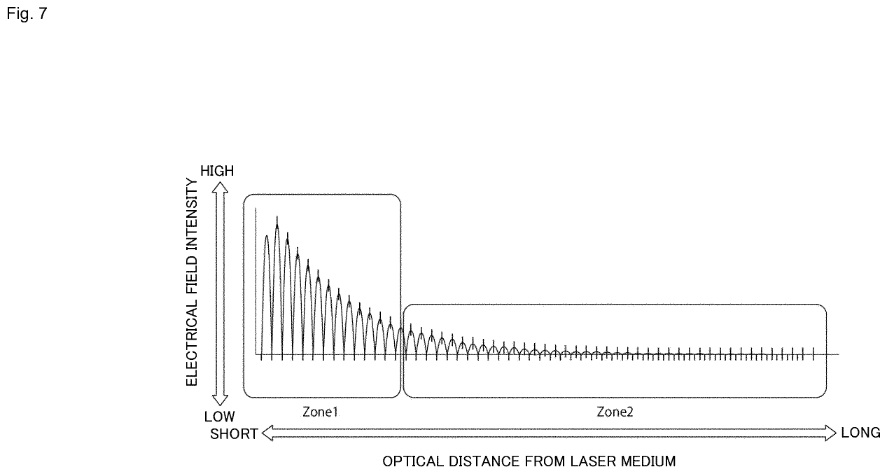

FIG. 7 is a graph showing characteristics of the second reflection layer R2 according to the second embodiment. In the graph in FIG. 7, the horizontal axis indicates an optical distance from the laser medium 3, and the vertical axis indicates an electrical field intensity. The second reflection layer R2 includes a first region of Zone 1 having a short optical distance from the laser medium 3 and a high electrical field intensity, and a second region of Zone 2 having a long optical distance from the laser medium 3 and a low electrical field intensity. Zone 1 is disposed on the rear side of the optical axis of the second reflection layer R2, and Zone 2 is disposed on the front side of the optical axis.

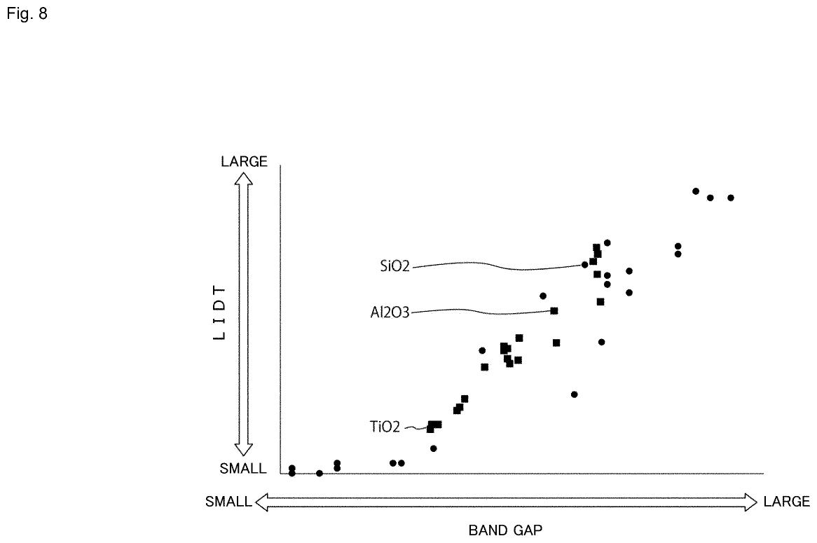

FIG. 8 is a graph showing characteristics of materials that can be used for the second reflection layer R2. In the graph in FIG. 8, the horizontal axis indicates a band gap, and the vertical axis indicates a Laser Induced Damaged Threshold (LIDT).

Zone 1 is configured by alternately laminating first material layers and second material layers having different refractive indices from each other. Furthermore, Zone 2 is also configured by alternately laminating third material layers and fourth material layers having different refractive indices from each other. A material of at least one of the first material layers and the second material layers in Zone 1 is different from a material of at least one of the third material layers and the fourth material layers in Zone 2.

Zone 1 is formed of a material having higher light durability than that of Zone 2. More specifically, two materials (e.g., SiO₂ and Al₂O₃) having a higher laser-induced damage threshold and a larger band gap are used for the first material layers and the second material layers of Zone 1. Consequently, it is possible to improve light durability against the oscillation light L2 of Zone 1 in the second reflection layer R2.

Zone 2 is formed of a material having higher light blocking performance than that of Zone 1. More specifically, two materials (e.g., SiO₂ and TiO₂) having a greater band gap difference, that is, a greater refractive index difference are used for the third material layers and the fourth material layers of Zone 2. Consequently, it is possible to improve the blocking characteristics for the oscillation light L2 of Zone 2 in the second reflection layer R2.

For example, as illustrated in FIG. 8, a lower (i.e., Al₂O₃) laser-induced damage threshold among the laser-induced damage threshold for the first material layers and the laser-induced damage threshold for the second material layers is made larger than a lower (i.e., TiO₂) laser-induced damage threshold among a laser-induced damage threshold for the third material layers and a laser-induced damage threshold for the fourth material layers. A difference between laser-induced damage thresholds of Zone 3 and Zone 4 is greater than the laser-induced damage thresholds of Zone 1 and Zone 2. Similarly, a lower band gap among a band gap of the first material layers and a band gap of the second material layers is larger than a lower band gap among a band gap of the third material layers and a band gap of the fourth material layers.

A plurality of materials are applicable to Zone 1 and Zone 2. For example, two or more of MgF₂, CaF₂, BaF₂, LiF, SiO₂, MgO, Al₂O₃, HfO₂, and ZrO₂ may be used for Zone 1. Furthermore, two or more of MgF₂, CaF₂, LiF, SiO₂, MgO, Al₂O₃, HfO₂, ZrO₂, TiO₂, Nb₂O₅, Ce₂O₃, WO₃, Yb₂O₃, Y₂O₃, Ta₂O₅, and ZnS may be used for Zone 2.

As described above, the second reflection layer R2 according to the second embodiment is divided into Zone 1 and Zone 2, and two or more materials having a larger laser induced damage threshold are used for Zone 1 having a higher electrical field intensity, and two or more materials having a larger refractive index difference are used for Zone 2 having a lower electrical field intensity. Consequently, the second reflection layer R2 can improve light durability in Zone 1 having the high electrical field intensity, and improve blocking characteristics in Zone 2 having the low electrical field intensity. Accordingly, even if the oscillation light L2 having an ultrashort pulse width and high peak power repeatedly enters the second reflection layer R2, it is possible to prevent optical damage of the second reflection layer R2, and reflect the oscillation light L2 without optical loss.

### Application Example

The technique according to the present disclosure can be applied to a medical imaging system. The medical imaging systems are medical systems that use an imaging technique, and are, for example, an endoscopic system and a microscopic system.

### [Endoscopic System]

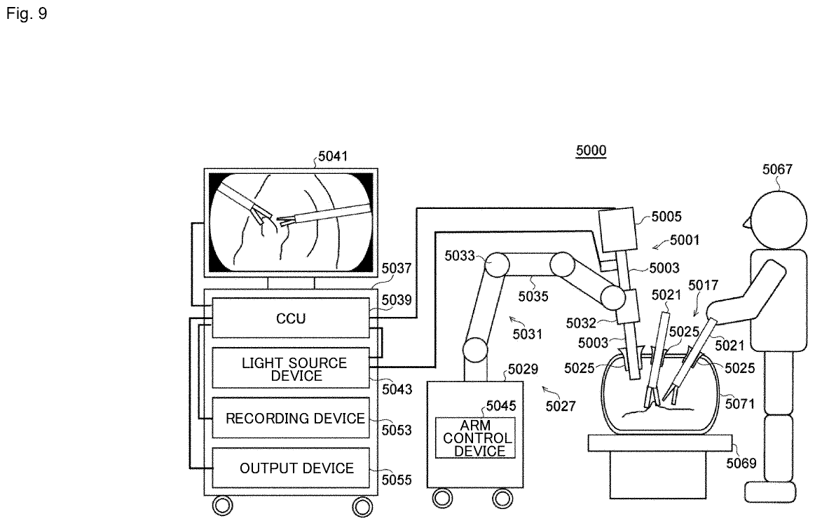

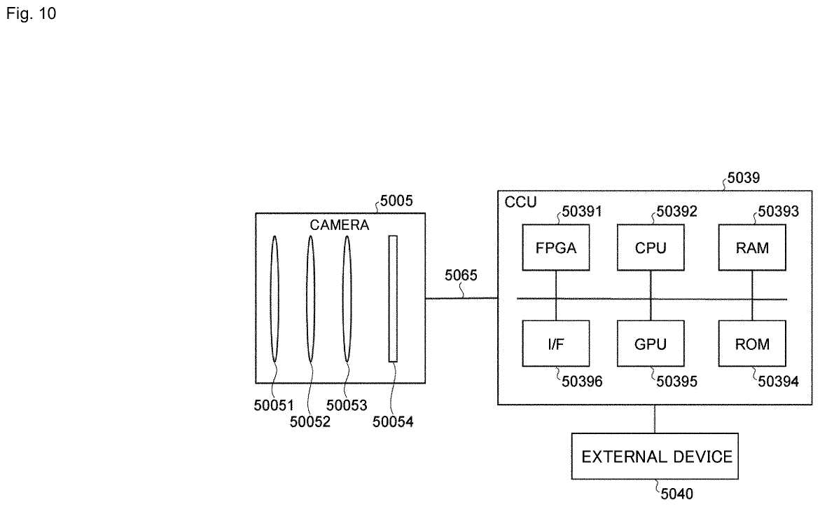

An example of an endoscopic system will be described with reference to FIGS. 9 and 10. FIG. 9 is a diagram illustrating an example of a schematic configuration of an endoscopic system 5000 to which the technique according to the present disclosure can be applied. FIG. 10 is a diagram illustrating an example of configurations of an endoscope 5001 and a Camera Control Unit (CCU) 5039. FIG. 9 illustrates a state where a surgeon (doctor) 5067 who is a surgery participant is performing a surgical operation on a patient 5071 on a patient bed 5069 by using the endoscopic system 5000. As illustrated in FIG. 9, the endoscopic system 5000 includes the endoscope 5001 that is the medical imaging device, the CCU 5039, a light source device 5043, a recording device 5053, an output device 5055, and a support device 5027 that supports the endoscope 5001.

According to an endoscopic surgical operation, an insertion auxiliary tool that is called a trocar 5025 is punctured to the patient 5071. Furthermore, a scope 5003 and a surgical tool 5021 connected to the endoscope 5001 are inserted into a body of the patient 5071 via the trocar 5025. Examples of the surgical tool 5021 are an energy device such as an electrical scalpel and a forcep.

A surgical operation image that is a medical image illustrating the interior of the body of the patient 5071 imaged by the endoscope 5001 is displayed on a display device 5041. The surgeon 5067 treats a surgical operation target using the surgical tool 5021 while looking at the surgical operation image displayed on the display device 5041. Note that the medical image is not limited to the surgical operation image, and may be a diagnosis image that is imaged during diagnosis.

### [Endoscope]

The endoscope 5001 is an imaging unit that images the interior of the body of the patient 5071, and is a camera 5005 that includes, for example, a condenser optical system 50051 that condenses incident light, a zoom optical system 50052 that changes a focal distance of the imaging unit and enables optical zoom, a focus optical system 50053 that changes the focal distance of the imaging unit and enables focus adjustment, and a light reception element 50054 as illustrated in FIG. 10. The endoscope 5001 generates a pixel signal by condensing the light on the light reception element 50054 via the connected scope 5003, and outputs the pixel signal to the CCU 5039 via a transmission system. Note that the scope 5003 is an insertion part that includes an objective lens at the distal end, and guides light from the connected light source device 5043 to the interior of the body of the patient 5071. The scope 5003 is, for example, a rigid scope in a case of a rigid mirror, and a flexible scope in a case of a flexible mirror. The scope 5003 may be a forward-viewing endoscope or a forward-oblique viewing endoscope. Furthermore, the pixel signal may be a signal that is based on a signal output from a pixel, and is, for example, a RAW signal or an image signal. Furthermore, a memory may be mounted on the transmission system that connects the endoscope 5001 and the CCU 5039, and the memory may be configured to store parameters related to the endoscope 5001 and the CCU 5039. The memory may be disposed, for example, at a connection portion or on a cable of the transmission system. For example, the memory of the transmission system stores parameters at a time of shipping of the endoscope 5001 or parameters that change at a time of power distribution, and an operation of the endoscope may be changed based on the parameters read from the memory. Furthermore, a set of the endoscope and the transmission system may be referred to as an endoscope. The light reception element 50054 is a sensor that converts received light into a pixel signal, and is, for example, a Complementary Metal Oxide Semiconductor (CMOS) type imaging element. The light reception element 50054 is preferably an imaging element that includes a Bayer layout and can perform color photographing. Furthermore, the light reception element 50054 is preferably an imaging element that includes the number of pixels matching a resolution of 4K (the number of horizontal pixels: 3840×the number of vertical pixels: 2160), 8K (the number of horizontal pixels: 7680×the number of vertical pixels: 4320), or square 4K (the number of horizontal pixels: 3840 or more×the number of vertical pixels: 3840 or more). The light reception element 50054 may be one sensor chip or may be a plurality of sensor chips. For example, a prism that splits incident light per predetermined wavelength band may be provided, and a different light reception element may be configured to image each wavelength band. Furthermore, a plurality of light reception elements may be provided for stereoscopic vision. Furthermore, the light reception element 50054 may be a sensor that includes an arithmetic processing circuit for image processing in a chip structure, and may be a Time of Flight (ToF) sensor. Note that the transmission system is, for example, an optical fiber cable or wireless transmission. Wireless transmission only needs to enable transmission of a pixel signal generated by the endoscope 5001, and, for example, the endoscope 5001 and the CCU 5039 may be wirelessly connected, or the endoscope 5001 and the CCU 5039 may be connected via a base station in an operating room. In this case, the endoscope 5001 may simultaneously transmit not only the pixel signal, but also information (e.g., a processing priority of the pixel signal, a synchronization signal, or the like) related to the pixel signal. There may be employed a configuration where the endoscope is integrated with the scope and the camera, and the light reception element is provided at a distal end part of the scope.

### [Camera Control Unit (CCU)]

The CCU 5039 is a control device that integrally controls the connected endoscope 5001 or light source device 5043, and is, for example, an information processing device that includes an FPGA 50391, a CPU 50392, a RAM 50393, a ROM 50394, a GPU 50395, and an I/F 50396 as illustrated in FIG. 10. Furthermore, the CCU 5039 may integrally control the connected display device 5041, the recording device 5053, and the output device 5055. For example, the CCU 5039 controls an irradiation timing, an irradiation intensity, an irradiation light source type of the light source device 5043. Furthermore, the CCU 5039 performs image processing such as development processing (e.g., demosaic processing) or correction processing on a pixel signal output from the endoscope 5001, and outputs the processed pixel signal (e.g., image) to an external device such as the display device 5041. Furthermore, the CCU 5039 transmits a control signal to the endoscope 5001, and controls driving of the endoscope 5001. The control signal is, for example, information related to imaging conditions such as a magnification and a focal distance of the imaging unit. Note that the CCU 5039 has an image down-conversion function, and may be configured to be able to simultaneously output a high-resolution (e.g., 4K) image to the display device 5041, and a low-resolution (e.g., HD) image to the recording device 5053.

The CCU 5039 may be connected with an external device (e.g., a recording device, a display device, an output device, or a support device) via an IP converter that converts a signal into a predetermined communication protocol (e.g., Internet Protocol (IP)). The connection of the IP converter and the external device may be configured by a wired network, or part or entirety of a network may be constructed as a wireless network. For example, the IP converter on the CCU 5039 side has a wireless communication function, and may transmit a received video to an IP switcher or an output side IP converter via a wireless communication network such as the fifth generation mobile communication system (5G) or the sixth generation mobile communication system (6G).

### [Light Source Device]

The light source device 5043 is a device that can radiate light of a predetermined wavelength band, and includes, for example, a plurality of light sources, and a light source optical system that guides light of the plurality of light sources. The light source is, for example, a xenon lamp, a LED light source, or an LD light source. The light source device 5043 includes LED light sources that are respectively associated with, for example, the three primary colors R, G, and B, and emit white light by controlling an output intensity or an output timing of each light source. Furthermore, the light source device 5043 may include a light source that can radiate special light used for special light observation in addition to a light source that radiates normal light used for normal light observation. The special light is light of a predetermined wavelength band different from the normal light that is light for normal light observation, and is, for example, near infrared light (light whose wavelength is 760 nm or more), infrared light, blue light, and ultraviolet light. The normal light is, for example, white light or green light. According to narrow band light observation that is one type of special light observation, it is possible to image predetermined tissues such as blood vessels of a mucous surface layer with a high contrast using wavelength dependency of absorption of light in body tissues by alternately radiating blue light and green light. Furthermore, according to fluorescence observation that is one type of special light observation, by radiating excitation light for exciting a drug injected into the body tissues, receiving fluorescence emitted from the drug that is the body tissues or a target, and obtaining a fluorescent image, the surgeon can easily visually check the body tissues or the like that the surgeon has difficulty in visually checking using the normal light. For example, according to fluorescence observation that uses the infrared light, it is possible to make it possible to easily visually check the structure or an affected part of the body tissues by radiating infrared light having an excitation wavelength band to a drug such as IndoCyanine Green (ICG) injected into the body tissues, and receiving the fluorescence of the drug. Furthermore, according to fluorescence observation, a drug (e.g., 5-ALA) that is excited by special light in a blue wavelength band and emits fluorescence of a red wavelength band may be used. Note that a type of irradiation light is set to the light source device 5043 under control of the CCU 5039. The CCU 5039 may have a mode that normal light observation and special light observation are alternately performed by controlling the light source device 5043 and the endoscope 5001. At this time, information based on a pixel signal obtained by special light observation is preferably superimposed on a pixel signal obtained by normal light observation. Furthermore, the special light observation may be infrared light observation for radiating infrared light and observing the depth beyond an organ front surface, or multispectral observation that utilizes hyperspectral spectroscopy. Furthermore, photodynamic therapy may be used in combination.

### [Recording Device]

The recording device 5053 is a device that records a pixel signal (e.g., image) acquired from the CCU 5039, and is, for example, a recorder. The recording device 5053 records in an HDD, an SDD, or an optical disk the image acquired from the CCU 5039. The recording device 5053 may be connected to a network in a hospital, and made accessible from a device outside of an operating room. Furthermore, the recording device 5053 may also have an image down-conversion function or up-conversion function.

### [Display Device]

The display device 5041 is, for example, a device that can display images, and is, for example, a display monitor. The display device 5041 displays a display image based on the pixel signal acquired from the CCU 5039. The display device 5041 may include a camera and a microphone to function as an input device that enables visual line recognition, voice recognition, and instruction input using a gesture.

### [Output Device]

The output device 5055 is a device that outputs information acquired from the CCU 5039, and is, for example, a printer. The output device 5055 prints on paper, for example, a print image based on the pixel signal acquired from the CCU 5039.

### [Support Device]

The support device 5027 is an articulated arm that includes a base part 5029 including an arm control device 5045, an arm part 5031 that extends from the base part 5029, and a holding part 5032 that is attached to the distal end of the arm part 5031. The arm control device 5045 includes a processor such as a CPU, and controls driving of the arm part 5031 by operating according to a predetermined program. The support device 5027 controls parameters such as the length of each link 5035 that constitutes the arm part 5031 and a rotation angle and a torque of each joint 5033 using the arm control device 5045 to control, for example, a position and a posture of the endoscope 5001 held by the holding part 5032. Consequently, it is possible to change the endoscope 5001 to a desired position or posture, insert the scope 5003 into the patient 5071, and change an observation region in the body. The support device 5027 functions an endoscope support arm that supports the endoscope 5001 during a surgical operation. Consequently, the support device 5027 can play a role of a scopist who is an assistant holding the endoscope 5001. Furthermore, the support device 5027 may be a device that supports a microscope device 5301 to be described later, and can be also referred to as a medical support arm. Note that control of the support device 5027 may be an autonomous control scheme that uses the arm control device 5045, or may be a control scheme that is controlled by the arm control device 5045 based on a user's input. For example, the control scheme may be a master/slave scheme that controls the support device 5027 that is a slave device (replica device) that is a patient cart based on a motion of a master device (primary device) that is a surgeon console at the hand of the user. Furthermore, the control of the support device 5027 may be able to be remotely controlled from the outside of the operating room.

An example of the endoscopic system 5000 to which the technique according to the present disclosure is applicable has been described above. For example, the technique according to the present disclosure may be applied to the microscopic system.

### [Microscopic System]

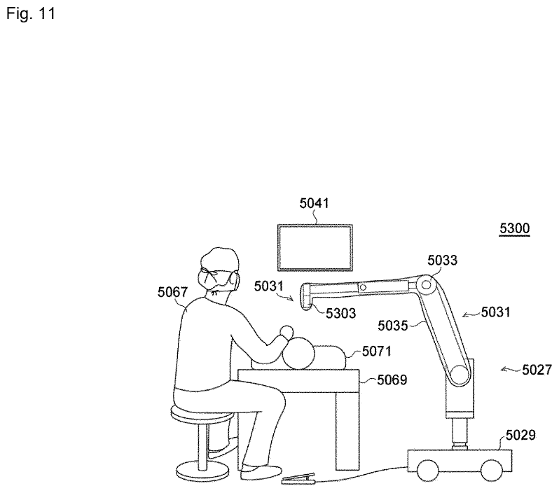

FIG. 11 is a diagram illustrating an example of a schematic configuration of a microsurgery system to which the technique according to the present disclosure is applicable. Note that, in the following description, the same components as those of the endoscopic system 5000 will be denoted by the same reference numerals and detailed description thereof will be omitted.

FIG. 11 schematically illustrates a state where the surgeon 5067 performs a surgical operation on the patient 5071 on the patient bed 5069 by using a microsurgery system 5300. Note that, in FIG. 11, for simplification, illustration of a cart 5037 of the configuration of the microsurgery system 5300 is omitted, and the microscope device 5301 in place of the endoscope 5001 is simplified and illustrated. In this regard, the microscope device 5301 in the description may indicate a microscope unit 5303 provided at the distal end of a link 5035, or may indicate the entire configuration including the microscope unit 5303 and the support device 5027.

As illustrated in FIG. 11, by using the microsurgery system 5300 during a surgical operation, an image of a surgical part imaged by the microscope device 5301 is displayed as an enlarged image on the display device 5041 installed in the operating room. The display device 5041 is installed to face the surgeon 5067, and the surgeon 5067 performs various treatment such as a resection of an affected part on the surgical part while observing a state of the surgical part through a video projected on the display device 5041. The microsurgery system is used for, for example, eye surgery and brain surgery.

The example of the endoscopic system 5000 and the microsurgery system 5300 to which the technique according to the present disclosure is applicable has been described above. Note that systems to which the technique according to the present disclosure is applicable are not limited to such an example. For example, the support device 5027 can also support another observation device or another surgical tool instead of the endoscope 5001 or the microscope unit 5303 at the distal end. The other observation device may be, for example, forceps, tweezers, a pneumoperitoneum tube for pneumoperitoneum, or an energy treatment instrument for incising tissues and sealing a blood vessel by cauterization. The observation device and the surgical tools are supported by the support device, so that the positions can be fixed with higher stability and the workload of the medical staff can be lighter than in manual support by the medical staff. The technique according to the present disclosure may be applied to such a support device that supports configurations other than a microscope unit.

The technique according to the present disclosure can be suitably applied to, for example, the light source device 5043 or the microscope device 5301 among the above-described components. When the technique according to the present disclosure is applied to the microscope device 5301, the microscope device 5301 can be applied as, for example, a two-photon microscope that utilizes a nonlinear effect induced by very large pulse energy of mode-locked laser light. By applying the technique according to the present disclosure to the microscope device 5301, it is possible to miniaturize and improve accuracy of the microscope device 5301, and it is possible to more safely and more reliably perform a surgical operation.

The present technique may have the following configurations.
(1) A laser element includes:
a laminated semiconductor layer that includes a first reflection layer for a first wavelength and an active layer that performs surface light emission at the first wavelength;
a laser medium that is disposed on a rear side of an optical axis of the laminated semiconductor layer, and includes a second reflection layer for a second wavelength on a first surface facing the laminated semiconductor layer and a third reflection layer for the first wavelength on a second surface on an opposite side to the first surface;
a fourth reflection layer for the second wavelength that is disposed further toward the rear side of the optical axis than the second surface;
a first resonator that resonates light of the first wavelength between the first reflection layer and the third reflection layer;
a second resonator that resonates light of the second wavelength between the second reflection layer and the fourth reflection layer; and
a semiconductor saturable absorber that is disposed between the third reflection layer and the fourth reflection layer and generates the light of the second wavelength by mode-locking, and the optical axis of the laminated semiconductor layer and an optical axis of the laser medium are uniaxially arranged.
(2) In the laser element described in (1), the laminated semiconductor layer, the laser medium, and the semiconductor saturable absorber are an integrated structure in which optical axes of the laminated semiconductor layer, the laser medium, and the semiconductor saturable absorber are uniaxially arranged.
(3) In the laser element described in (1) or (2), the semiconductor saturable absorber includes a quantum well structure that has a predetermined modulation depth and a recovery time.
(4) In the laser element described in (3), the semiconductor saturable absorber is of a transmission type and has a modulation depth ΔR of 0.5 to 2%, and a recovery time τ_{fast} of less than 500 fs (femtoseconds).
(5) In the laser element described in any one of (1) to (4), the laser medium is a solid-state laser medium.
(6) In the laser element described in (4), the laser medium is an ion-doped type solid-state laser medium.
(7) In the laser element described in any one of (1) to (6), the second resonator includes a chirp mirror.
(8) In the laser element described in (7), at least one of the second reflection layer and the fourth reflection layer is the chirp mirror.
(9) In the laser element described in (7) to (8), when a group delay dispersion GDD_{cavity} of the chirp mirror, a group delay dispersion GDD_{gain medium} of the laser medium, and a group delay dispersion GDD_{SA} of the semiconductor saturable absorber satisfy a relationship of a following (expression 1)

$${GDD}_{cavity} = 2 {GDD}_{gain medium} + 2 {GDD}_{DBR} + {GDD}_{SA} , \qquad ( Expression 1 )$$

the group delay dispersion GDD_{cavity} of the chirp mirror is set to satisfy a following (expression 2)

$$- 2000 {fs}^{2} < {GDD}_{cavity} < 2000 {fs}^{2} . \qquad ( Expression 2 )$$

(10) In the laser element described in any one of (1) to (9), the second reflection layer is a shortwave wavelength transmission filter.
(11) In the laser element described in (10), the second reflection layer includes a first region disposed on the rear side of the optical axis, and
a second region laminated on the first region and disposed on a front side of the optical axis,
the first region is formed of a material having higher light durability than light durability of the second region, and
the second region is formed of a material having higher light blocking performance than light blocking performance of the first region.
(12) In the laser element described in (11), the first region is formed by alternately laminating a first material layer and a second material layer having different refractive indices from each other, and
the second region is formed by alternately laminating a third material layer and a fourth material layer having different refractive indices from each other.
(13) In the laser element described in (12), a difference between the refractive indices of the third material layer and the fourth material layer is greater than a difference between the refractive indices of the first material layer and the second material layer.
(14) In the laser element described in (12) or (13), a difference between band gaps of the third material layer and the fourth material layer is greater than a difference between band gaps of the first material layer and the second material layer.
(15) In the laser element described in any one of (12) to (14), a difference between laser-induced damage thresholds of the third material layer and the fourth material layer is greater than a difference between laser-induced damage thresholds of the first material layer and the second material layer.
(16) In the laser element described in any one of (1) to (15), a degree of a difference among thermal expansion coefficients of the laminated semiconductor layer, the laser medium, and the semiconductor saturable absorber is 20% or less.
(17) An electronic device includes:
a laser element; and
an imaging unit that generates image data, based on irradiation light of the laser element or reflection light of the irradiation light, the laser element includes:
a laminated semiconductor layer that includes a first reflection layer for a first wavelength and an active layer that performs surface light emission at the first wavelength;
a laser medium that is disposed on a rear side of an optical axis of the laminated semiconductor layer, and includes a second reflection layer for a second wavelength on a first surface facing the laminated semiconductor layer and a third reflection layer for the first wavelength on a second surface on an opposite side to the first surface;
a fourth reflection layer for the second wavelength that is disposed further toward the rear side of the optical axis than the second surface;
a first resonator that resonates light of the first wavelength between the first reflection layer and the third reflection layer;
a second resonator that resonates light of the second wavelength between the second reflection layer and the fourth reflection layer; and
a semiconductor saturable absorber that is disposed between the third reflection layer and the fourth reflection layer and generates the light of the second wavelength by mode-locking, and
the optical axis of the laminated semiconductor layer and an optical axis of the laser medium are uniaxially arranged.

Aspects of the present disclosure are not limited to the aforementioned individual embodiments and include various modifications that could be conceived of by a person skilled in the art, and effects of the present disclosure are also not limited to those described above. In other words, various additions, modifications, and partial deletions can be made without departing from the conceptual ideas and spirit of the present disclosure that can be derived from the details defined in the claims and the equivalents thereof.

### REFERENCE SIGNS LIST

1, 1a, 50 Laser element
2 Excitation light source
3, 54 Laser medium
4, 53 Saturable absorber
11, 11a First resonator
12, 12a Second resonator
21 Substrate
22, 24 Cladding layer
23 Active layer
25 Quantum well
31, 32 Contact layer
41 n electrode
42, 45 Insulation layer
43 PAD
44 Plating layer
46 p electrode
47 Oxide layer
51 Heat sink
52 Output coupler
54 Gain medium
55 AR member
100 Laser device

1. A laser element comprising:
a laminated semiconductor layer that includes a first reflection layer for a first wavelength and an active layer that performs surface light emission at the first wavelength;
a laser medium that is disposed on a rear side of an optical axis of the laminated semiconductor layer, and includes a second reflection layer for a second wavelength on a first surface facing the laminated semiconductor layer and a third reflection layer for the first wavelength on a second surface on an opposite side to the first surface;
a fourth reflection layer for the second wavelength that is disposed further toward the rear side of the optical axis than the second surface;
a first resonator that resonates light of the first wavelength between the first reflection layer and the third reflection layer;
a second resonator that resonates light of the second wavelength between the second reflection layer and the fourth reflection layer; and
a semiconductor saturable absorber that is disposed between the third reflection layer and the fourth reflection layer and generates the light of the second wavelength by mode-locking,
wherein the optical axis of the laminated semiconductor layer and an optical axis of the laser medium are uniaxially arranged.

2. The laser element according to claim 1, wherein the laminated semiconductor layer, the laser medium, and the semiconductor saturable absorber are an integrated structure in which optical axes of the laminated semiconductor layer, the laser medium, and the semiconductor saturable absorber are uniaxially arranged.

3. The laser element according to claim 1, wherein the semiconductor saturable absorber includes a quantum well structure that has a predetermined modulation depth and a recovery time.

4. The laser element according to claim 3, wherein the semiconductor saturable absorber is of a transmission type and has a modulation depth ΔR of 0.5 to 2%, and a recovery time τ_{fast} of less than 500 fs (femtoseconds).

5. The laser element according to claim 1, wherein the laser medium is a solid-state laser medium.

6. The laser element according to claim 4, wherein the laser medium is an ion-doped type solid-state laser medium.

7. The laser element according to claim 1, wherein the second resonator includes a chirp mirror.

8. The laser element according to claim 7, wherein at least one of the second reflection layer and the fourth reflection layer is the chirp mirror.

9. The laser element according to claim 7, wherein, when a group delay dispersion GDD_{cavity} of the chirp mirror, a group delay dispersion GDD_{gain medium} of the laser medium, and a group delay dispersion GDD_{SA} of the semiconductor saturable absorber satisfy a relationship of following expression (1)
$${GDD}_{cavity} = 2 {GDD}_{gain medium} + 2 {GDD}_{DBR} + {GDD}_{SA} , \qquad ( 1 )$$
the group delay dispersion GDD_{cavity} of the chirp mirror is set to satisfy following expression (2)
$$- 2000 {fs}^{2} < {GDD}_{cavity} < 2000 {fs}^{2} . \qquad ( 2 )$$

10. The laser element according to claim 1, wherein the second reflection layer is a shortwave wavelength transmission filter.

11. The laser element according to claim 10, wherein
the second reflection layer includes
a first region disposed on the rear side of the optical axis, and
a second region laminated on the first region and disposed on a front side of the optical axis,
the first region is formed of a material having higher light durability than light durability of the second region, and
the second region is formed of a material having higher light blocking performance than light blocking performance of the first region.

12. The laser element according to claim 11, wherein
the first region is formed by alternately laminating a first material layer and a second material layer having different refractive indices from each other, and
the second region is formed by alternately laminating a third material layer and a fourth material layer having different refractive indices from each other.

13. The laser element according to claim 12, wherein a difference between the refractive indices of the third material layer and the fourth material layer is greater than a difference between the refractive indices of the first material layer and the second material layer.

14. The laser element according to claim 12, wherein a difference between band gaps of the third material layer and the fourth material layer is greater than a difference between band gaps of the first material layer and the second material layer.

15. The laser element according to claim 12, wherein a difference between laser-induced damage thresholds of the third material layer and the fourth material layer is greater than a difference between laser-induced damage thresholds of the first material layer and the second material layer.

16. The laser element according to claim 1, wherein a degree of a difference among thermal expansion coefficients of the laminated semiconductor layer, the laser medium, and the semiconductor saturable absorber is 20% or less.

17. An electronic device comprising:
a laser element; and
an imaging unit that generates image data, based on irradiation light of the laser element or reflection light of the irradiation light,
the laser element includes:
a laminated semiconductor layer that includes a first reflection layer for a first wavelength and an active layer that performs surface light emission at the first wavelength;
a laser medium that is disposed on a rear side of an optical axis of the laminated semiconductor layer, and includes a second reflection layer for a second wavelength on a first surface facing the laminated semiconductor layer and a third reflection layer for the first wavelength on a second surface on an opposite side to the first surface;
a fourth reflection layer for the second wavelength that is disposed further toward the rear side of the optical axis than the second surface;
a first resonator that resonates light of the first wavelength between the first reflection layer and the third reflection layer;
a second resonator that resonates light of the second wavelength between the second reflection layer and the fourth reflection layer; and
a semiconductor saturable absorber that is disposed between the third reflection layer and the fourth reflection layer and generates the light of the second wavelength by mode-locking,
wherein the optical axis of the laminated semiconductor layer and an optical axis of the laser medium are uniaxially arranged.
